(19) United States
(12) Patent Application Publication
(10) Pub. No.: US 2010/0276747 A1
(43) Pub. Date: Nov. 4, 2010

(54) Charge trapping layer, method of forming the charge trapping layer, non-volatile memory device using the same and method of fabricating the non-volatile memory device

(76) Inventors: Jang-Sik Lee, Seoul (KR); Byeong Hyeok Sohn, Seoul (KR); Yong Mu Kim, Seoul (KR); Jeong Hwa Kwon, Gyeonggi-do (KR); Hyunjung Shin, Gyeonggi-do (KR); Jaegab Lee, Seoul (KR)

Correspondence Address: ROSENBERG, KLEIN & LEE, 3458 ELLICOTT CENTER DRIVE-SUITE 101, ELLICOTT CITY, MD, 21043, US

(21) Appl. No.: 12/588,871

(22) Filed: Oct. 30, 2009

(30) Foreign Application Priority Data
Apr. 30, 2009 (KR) 10-2009-0038534

(51) Int. Cl. H01L 29/792; H01L 29/51; H01L 21/31; H01L 21/28

(52) U.S. Cl. 257/325; 257/632; 438/761; 438/591; 257/E29.165; 257/E29.309; 257/E21.24; 257/E21.21

(57) ABSTRACT

Provided is a charge trapping layer which has excellent memory characteristics, a method of forming the charge trapping layer, a nonvolatile memory device using the charge trapping layer, and a method of fabricating the nonvolatile memory device, in which a hybrid nanoparticle which is obtained by mixing a nanoparticle having an excellent programming characteristic with a nanoparticle having an excellent erasing characteristic is used as the charge trapping layer. The charge trapping layer for use in the nanoparticle is discontinuously formed between a tunneling oxide film and a control oxide film, and includes at least two different kinds of numerous nanoparticles.

### CROSS-REFERENCE TO RELATED APPLICATION

This application claims the benefit of Korean Patent Application No. 10-2009=0038534, filed on Apr. 30, 2009, in the Korean Intellectual Property Office, the disclosure of which is incorporated herein by reference. This invention is based on the works supported by the National Research Foundation of Korea (grant no. R11-2005-048-00000-0, 2008-0059952, 2009-0077593, 313-2008-2-D00597) and World Gold Council (grant no. RP05-08).

### BACKGROUND OF THE INVENTION

1. Field of the Invention

The present invention relates to a charge trapping layer, a method of forming the charge trapping layer, a nonvolatile memory device using the charge trapping layer, and a method of fabricating the nonvolatile memory device. More particularly, the present invention relates to a charge trapping layer, a method of forming the charge trapping layer, a nonvolatile memory device using the charge trapping layer, and a method of fabricating the nonvolatile memory device, in which a hybrid nanoparticle which is obtained by mixing a nanoparticle having an excellent program characteristic with a nanoparticle having an excellent erasure characteristic is used as the charge trapping layer.

2. Description of the Related Art

According to development of a semiconductor device technology, semiconductor devices, for example, semiconductor memory devices, or thin film transistor-liquid crystal displays (TFT-LCD's) are tending high integrated and miniaturized.

Semiconductor memory devices are largely classified into a volatile memory device such as a dynamic random access memory (DRAM) and a static random access memory (SRAM) in which stored data is lost if electric power is interrupted, and a nonvolatile memory device in which stored data is kept even if electric power is temporarily interrupted.

Nonvolatile memory devices have a substantially limitless cumulative capacity, respectively. A demand for flash memory devices that enable data to be electrically input and output, for example, an electrically erasable and programmable read-only memory (EEPROM) is increasing.

A flash memory device which is one of nonvolatile memory devices can be largely classified into a floating gate type flash memory device and SONOS (Silicon-Oxide-Nitride-Oxide-Semiconductor) type flash memory device according to a charge storage structure.

The floating gate type flash memory device generally has a vertical deposition style multi-layer gate structure having a floating gate on a silicon substrate. Here, the multi-layer gate structure includes at least one tunnel oxide film or dielectric film, a floating gate formed on the tunnel oxide film, and a control gate formed on the floating gate.

In the case of the floating gate type flash memory device, a proper voltage is applied to the control gate and the substrate, to thus make charges flow in/drain from the floating gate and to thereby record/delete data. The dielectric film maintains charges charged in the floating gate.

The SONOS type flash memory device includes a source electrode and a drain electrode which are formed in a silicon substrate, a tunnel oxide film which is deposited on the upper surface of the silicon substrate, a nitride film which is deposited on the upper surface of the tunnel oxide film, an blocking oxide film which is formed on the upper surface of the nitride film, and a gate electrode which is formed on the upper surface of the blocking oxide film, in which the tunnel oxide film, the nitride film, and the blocking oxide film are generally called an ONO (Oxide/Nitride/Oxide) film.

The SONOS type flash memory device can operate as a memory device that stores information in which electrons are captured in charge defects formed in the inside of the nitride film formed on the upper surface of the tunnel oxide film. However, it is hard to adjust or control the number of the charge defects in the inside of the nitride film which captures electrons.

Meanwhile, a study tending to use nanocrystals whose particle density and size can be easily controlled as a floating gate in the floating gate type flash memory device is in progress.

In order to form such nanocrystals on a tunnel oxide film of silicon substrate, a high-temperature heat treatment process is needed at 850° C. or higher.

However, when a high-temperature heat treatment process proceeds to form nanocrystals in a silicon substrate, a film quality characteristic of each component for example, a tunnel oxide film may change according to an interface reaction and defect. Problems such as components of various film qualities and unnecessary diffusion of ions due to an ion implantation process may occur, to thus deteriorate characteristics of the components.

Therefore, a technology of manufacturing a floating gate type flash memory device that can prevent problems which may be caused by a high-temperature heat treatment process while taking the merits of nanocrystals, by using nanocrystals whose density and size can be easily controlled in a floating gate which floats electric charges, is required.

Meanwhile, a method of manufacturing a nanodot memory is disclosed in Korean Laid-open Patent Publication No. 10-2007-25519, in which a metallic nanodot colloidal solution is deposited on an insulator film that is formed on a substrate and density of equal nanodot particles is controlled when a solvent in the solution is evaporated, to thus form a nanodot particle layer as a single layer. However, since the method of manufacturing a nanodot memory disclosed in Korean Laid-open Patent Publication No. 10-2007-25519 is not a method of arranging nanodot particles by using a self-assembly method, it is difficult to control arrangement and density of uniform nanodot particles.

Considering the problem, the same applicant as that of this invention proposed a method of forming a floating gate, a nonvolatile memory device using the same, and a method of manufacturing the nonvolatile memory device in Korean Laid-open Patent Publication No. 10-2008-88214, in which nanocrystals of nano size are synthesized using micelles without having a high-temperature heat treatment process, to thereby manufacture the floating gate that can be used as that of a nonvolatile memory device and whose density and size can be easily controlled.

The method of forming a floating gate is a method of forming a floating gate on a semiconductor substrate, and includes: a step of forming a tunneling oxide film on the semiconductor substrate; a step of coating on the tunneling oxide film a gate formation solution including a micelle template into which a precursor that can synthesize a metallic salt is introduced in a nanostructure which is formed by a self-assembly method; and a step of removing the micelle template of the semiconductor substrate and arranging the metallic salt on the tunneling oxide film to thus form the floating gate.

The floating gates for use in the nonvolatile memory device that is obtained by the method are used by forming a single kind of a metal nanocrystal using the micelle template.

However, the nonvolatile memory device (for example, a flash memory device) that uses the metal nanocrystal (for example, a nanoparticle) of the single kind which is disclosed in Korean Laid-open Patent Publication No. 10-2008-88214 as a floating gate (for example, a charge trapping layer) has a shortcoming that memory characteristics are limited by physical and chemical characteristics such as a work function, etc., of the nanoparticle.

That is, a capability of trapping charges is decided according to electron affinity/ionization energy of nanoparticles and difference of memory characteristics is also seen according to surface states of nanoparticles.

For example, since surface oxidation is easily made in the case of cobalt nanoparticles of single kind, the cobalt nanoparticles become a core/shell structure including metal cobalt/cobalt oxide by a surface oxidation layer, to resultantly make it difficult to perform an erasure operation. Meanwhile, since gold nanoparticles include electrons from an initial state, an erasure operation is more easily performed by the stored electrons in the case of the gold nanoparticles than the case of the cobalt nanoparticles, at the time of the erasure operation.

In addition, since cobalt nanoparticles include few electrons at an initial state, a program operation can be made well, in the case of the cobalt nanoparticles. Meanwhile, since gold nanoparticles have very large electron affinity and thus already include electrons at an initial state, the electrons can be trapped by a Coulomb repulsion force to a degree. However, it is difficult for the gold nanoparticles to trap electrons due to a Coulomb blockade effect of the already-stored electrons in comparison with the cobalt nanoparticles. Owing to these characteristics of the gold nanoparticles, it is difficult to perform a program operation in the case of the gold nanoparticles.

For example, when cobalt nanoparticles that include a single element are used as an information storage layer, it can be confirmed that a program characteristic is made better than an erasure characteristic. On the other hand, in the case that gold nanoparticles are used as an information storage layer, it can be confirmed from a memory operating characteristic which will be described later of FIG. 6 that an erasure characteristic is made better than a program characteristic.

### SUMMARY OF THE INVENTION

To overcome inconveniences of the conventional art, it is an object of the present invention to provide a nonvolatile memory device having an excellent memory characteristic, and a method of fabricating the same, in which hybrid nanoparticles which are obtained by mixing a nanoparticle having an excellent program characteristic with a nanoparticle having an excellent erasure characteristic is used as a charge trapping layer.

It is another object of the present invention to provide a charge trapping layer for use in a nonvolatile memory device and a method of fabricating the same, in which the charge trapping layer including nanoparticle can be formed by easily controlling density, size and kind of the nanoparticle by a self-assembly method using micelle templates.

It is still another object of the present invention to provide a nonvolatile memory device having an adjustable memory characteristic which is obtained by using a mixture layer of hybrid nanoparticle as an information storage layer and which cannot be obtained in a memory device using nanoparticle of a single element.

It is yet another object of the present invention to provide a multiplex data level programmable/accessible nonvolatile memory device using a programmable memory characteristic having a flat band voltage which differs from each other according to kind of a charge trapping layer.

It is still yet another object of the present invention to provide a nonvolatile memory device to which high voltage can be applied so that breakdown does not occur although high program bias voltage is applied to a gate, to thereby perform an excellent program operation.

According to a first aspect of the present invention to achieve the objects, there is provided a charge trapping layer for use in a nonvolatile memory device, the charge trapping layer comprising a number of nanoparticles which are discontinuously formed between a tunneling barrier layer and a control barrier layer, and comprise at least two respectively different kinds of elements.

According to a second aspect of the present invention, there is provided a nonvolatile memory device comprising: a semiconductor substrate; a tunneling barrier layer formed on the semiconductor substrate; a charge trapping layer comprising a number of nanoparticles discontinuously formed on the tunneling barrier layer and comprise at least two respectively different kinds of elements; a control barrier layer formed on the tunneling barrier layer and the nanoparticles of the charge trapping layer; and a control gate formed on the control barrier layer.

According to a third aspect of the present invention, there is provided a method of forming a charge trapping layer on a semiconductor substrate, the method comprising the steps of forming a tunneling barrier layer on the semiconductor substrate; preparing at least two different kinds of charge trapping layer formation solutions in which a block copolymer micelle that is composed of a soluble corona block and an insoluble core block in solvents and that forms a nanostructure by a self-assembly method, and at least two different kinds of inorganic precursors are dissolved in the solvents, respectively, and thus the inorganic precursors are selectively introduced in the core block playing a role of a micelle template; mixing the at least two different kinds of charge trapping layer formation solutions at a desired ratio, to thus obtain a charge trapping layer formation solution mixture; coating the mixture on the tunneling barrier layer and arranging a number of micelle templates into which the inorganic precursors are respectively introduced by the self-assembly method; and removing the micelle templates to thus arrange different kinds of nanoparticles which are synthesized from the inorganic precursors on the tunneling barrier layer in a predetermined pattern of nano size and to thereby form a charge trapping layer.

According to forth aspect of the present invention, there is provided a method of fabricating, a nonvolatile memory device, the method comprising the steps of forming a tunneling barrier layer on a semiconductor substrate; preparing at least two different kinds of charge trapping layer formation solutions in which a block copolymer micelle that is composed of a soluble corona block and an insoluble core block in solvents and that forms a nanostructure by a self-assembly method, and at least two different kinds of inorganic precursors are dissolved in the solvents, respectively, and thus the inorganic precursors are selectively introduced in the core block playing a role of a micelle template; mixing the at least two different kinds of charge trapping layer formation solutions at a desired ratio, to thus obtain a charge trapping layer formation solution mixture; coating the mixture on the tunneling barrier layer; removing the micelle templates to thus arrange different kinds of nanoparticles which are synthesized from the inorganic precursors on the tunneling barrier layer in a predetermined pattern of nano size and to thereby form a charge trapping layer; forming a control oxide film on the tunneling oxide film and the nanoparticles; and forming a control gate on the control oxide film.

### BRIEF DESCRIPTION OF THE DRAWINGS

The above and/or other aspects of the present invention will become apparent and more readily appreciated from the following description of the exemplary embodiments, taken in conjunction with the accompanying drawings in which:

FIG. 1 is a partially cutoff perspective view showing structure of a nonvolatile memory device in which hybrid nanoparticles are employed as a charge trapping layer, according to a preferred embodiment of the present invention;

FIGS. 2A through 2H are process cross-sectional views, respectively, for explaining a method of manufacturing a nonvolatile memory device illustrated in FIG. 1;

FIG. 3 is a diagram for explaining a process of preparing a copolymer micelle solution which is applied to a preferred embodiment of the present invention;

FIG. 4 is a diagram for explaining a synthesis of hybrid nanoparticles according to a preferred embodiment of the present invention;

FIGS. 5A through 5C are SEM (Scanning Electron Microscopy) pictures that show enlarged images of nanoparticles of cobalt (Co), nanoparticles of gold (Au) nanoparticles, and nanoparticles of a mixture of Co and Au after plasma treatment, respectively;

FIG. 6 is a graphical view that represents' a memory effect of a nonvolatile memory device as capacitance values in which the conventional nonvolatile memory device uses Co and Au nanoparticles, respectively as a charge trapping layer and the nonvolatile memory device according to this invention uses nanoparticles of a mixture of Co and Au as a charge trapping layer;

FIG. 7 is a graphical view that represents a memory effect of a nonvolatile memory device as tunneling electric current density values in which the conventional nonvolatile memory device uses Co and Au nanoparticles, respectively as a charge trapping layer and the nonvolatile memory device according to this invention uses nanoparticles of a mixture of Co and Au as a charge trapping layer;

FIG. 8 is a graphical view that represents change of a flat voltage by change of time in a nonvolatile memory device in which hybrid nanoparticles are fabricated as a charge trapping layer;

FIGS. 9A through 9C are pictures showing a memory effect measured by Kelvin Force Microscopy (KFM) in nano scale in a nonvolatile memory device in which hybrid nanoparticles are used as a charge trapping layer; and

FIG. 10 is a graphical view that represents a flat band voltage shift in a nonvolatile memory device in which hybrid nanoparticles are used as a charge trapping layer.

### DETAILED DESCRIPTION OF THE INVENTION

Hereinbelow, a charge trapping layer, a method of forming the charge trapping layer, a nonvolatile memory device using the charge trapping layer, and a method of fabricating the nonvolatile memory device according to the present invention will be described with reference to the accompanying drawings.

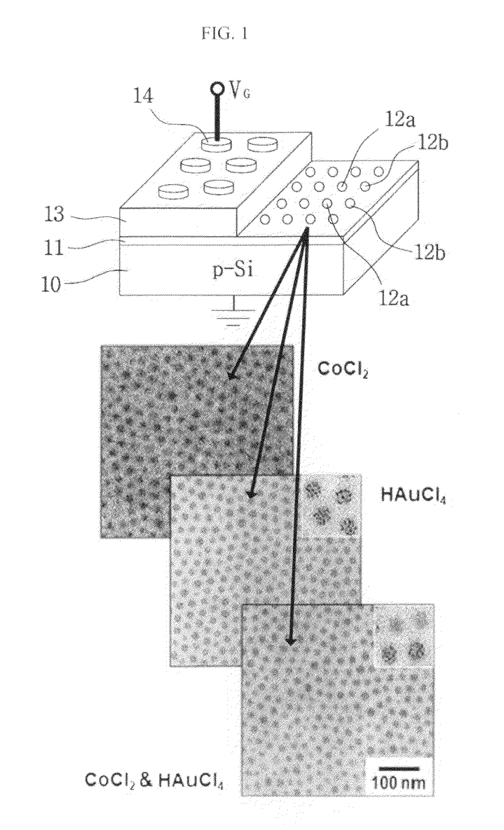

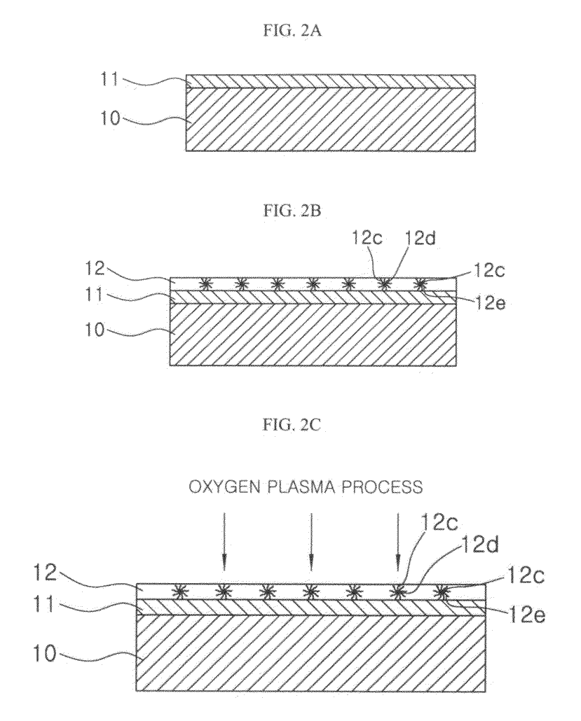

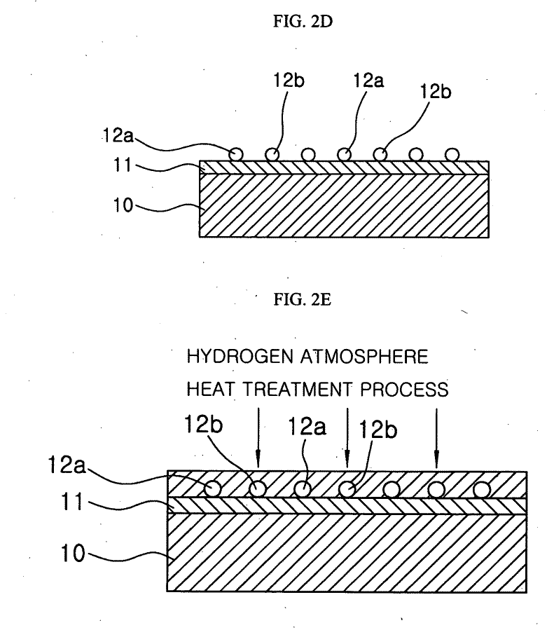

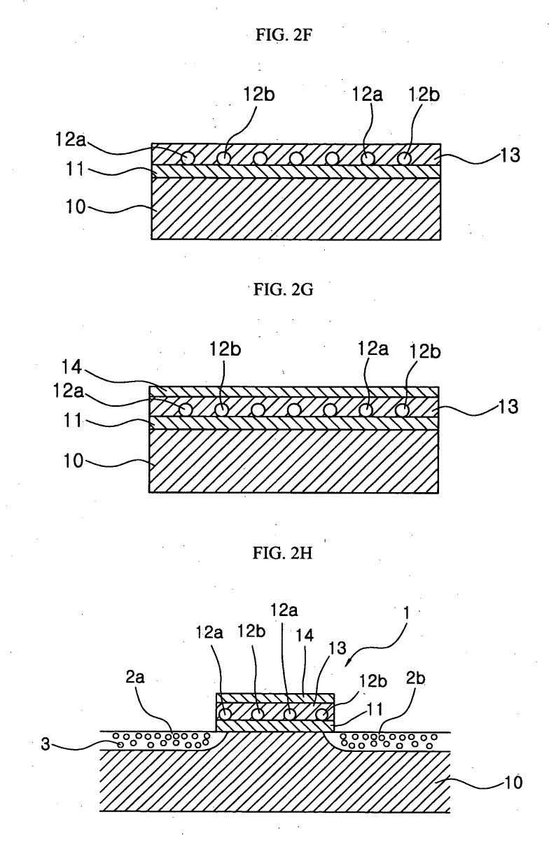

FIG. 1 is a partially cutoff perspective view showing structure of a nonvolatile memory device in which hybrid nanoparticles are employed as a charge trapping layer, according to a preferred embodiment of the present invention, and FIGS. 2A through 2H are process cross-sectional views, respectively, for explaining a method of manufacturing a nonvolatile memory device illustrated in FIG. 1.

Referring to FIG. 1, a floating gate type nonvolatile memory device according to a preferred embodiment of this invention includes: a tunneling oxide film 11 formed on the upper surface of a silicon substrate 10; a charge trapping layer formed on the upper surface of the tunneling oxide film 11 in which at least two kinds of nanoparticles 12a and 12b is discontinuously arranged as the charge trapping layer; and a gate structure in which a control oxide film 13 and a control gate 14 are sequentially deposited.

As shown in FIG. 2H, a source region 2a and a drain region 2b both in which impurities 3 are doped are also formed on the silicon substrate 10, and a channel region is formed in the lower side of the gate structure, that is, between the source region 2a and the drain region 2b.

The tunneling oxide film 11 formed in the upper surface of the silicon substrate 10 has a structure that any one or at least two of for example, HfO₂, SiO₂ and Al₂O₃ of 0.9-1.9 nm thick are deposited.

The charge trapping layer formed on the upper portion of the tunneling oxide film 11 by a self-assembly method using micelle has a structure that at least two kinds of numerous nanoparticles 12a and 12b are discontinuously arranged. Each of the at least two kinds of the nanoparticles 12a and 12b forms a trap when charges such as electrons or holes move from the silicon substrate 10 according to voltage that is applied to the control gate 14.

In this case, the charge trapping layer may be made of inorganic substances including metals and semiconductor materials.

In this case, the two kinds of the nanoparticles 12a and 12b are preferably made in view of a memory characteristic by mixing a first kind of nanoparticles used for programming operations

and a second kind of nanoparticles used for erasing operations in combination. In addition, it is possible to mix and arrange two or more kinds of nanoparticles as necessary, in the case of the hybrid nanoparticles which are formed by mixing the different kinds of nanoparticles.

For example, cobalt (Co) and copper (Cu) may be used as the first kind of nanoparticles having excellent programming operations, and gold (Au) and platinum (Pt) may be used as the second kind of nanoparticles having excellent erasing operations.

For example, nanoparticles obtained by mixing Co nanoparticles 12a and Au nanoparticles 12b in combination are used in the following embodiments.

The nanoparticles are made of one kind of metal nanoparticles among Fe, Ni, Cr, Ag, Cu, Al, Pt, Sn, W, Ru, Pd and Cd, or semiconductor nanoparticles including Si, Ge, and SiGe, in addition to Au and Co.

In this case, the metal nanoparticles have preferably a size between 0.1 nm and 100 nm. That is, there are problems that it is impossible to manufacture the metal nanoparticles in the case that the metal nanoparticles have a size of less than 0.1 nm and a gate structure exceeds an allowable thickness in the case that the metal nanoparticles have a size of more than 100 nm.

The control oxide film 13 formed in the upper surface of the metal nanoparticles has a structure that any one or at least two of for example, HfO₂, SiO₂ and Al₂O₃ are deposited in the same manner as that of the tunneling oxide film 11.

The control gate 14 that acts as a gate electrode can be formed of a conductive film and platinum, titanium, titanium nitride, tantalum, tantalum nitride, etc., may be used as an example of metal.

As described above, in the case of the nonvolatile memory device of this invention, a number of nanoparticles 12a and 12b made of different kinds of nanoparticles playing a role of a charge trapping layer are discontinuously formed at intervals between the tunneling oxide film 11 and the control oxide film 13.

Since the nonvolatile memory device of this invention as described above uses at least two kinds of nanoparticles 12a and 12b as a charge trapping layer, preferably hybrid nanoparticles which are obtained by mixing nanoparticles having excellent programming operations and nanoparticles having excellent erasing operations, it can be seen that the nonvolatile memory device of this invention has a memory characteristic with a greatly increased memory window as shown in FIG. 6.

The hybrid nanoparticles 12a and 12b which accomplishes the charge trapping layer traps charges and then stores or emits the trapped charges. That is, when positive voltage is applied to the control gate during programming, charges are respectively scattered and injected into Co and Au nanoparticles. In this case, since the nanoparticles are spaced from one another, transfer of charges is limited among the nanoparticles. Thus, although defects occur in part of the tunneling oxide film 11, leakage current due to the defects is trapped by the adjoining nanoparticles. As a result, the charges do not leak. to thus enhance a data maintenance characteristic.

Also, when a programming or erasing operation is not performed in the nonvolatile memory device of this invention, the control oxide film 13 plays a role of preventing the charges which are stored in the nanoparticles 12a and 12b from being emitted to the control gate 14, that is, the gate electrode that is formed on the upper portion of the nanoparticles, or the charges from being injected into the nanoparticles 12a and 12b from the electrode.

Also, the control oxide film 13 should be configured so that most of voltage that is applied from the control gate 14 is applied to the tunneling oxide film 11 during the programming or erasure operation.

The metal oxide may be formed of aluminum oxide (Al₂O₃), zirconium oxide, zirconium silicate, hafnium oxide (HfO₂), hafnium silicate, etc. The metal oxide may have a structure that a single one or at least two selected from the group consisting of aluminum oxide (Al₂O₃), zirconium oxide, zirconium silicate, hafnium oxide (HfO₂), and hafnium silicate are epitaxially laminated.

In the case of the nonvolatile memory device configured as described above, the control oxide film 13 performs the same function as that of a dielectric film in an existent MOS (Metal-Oxide-Semiconductor) structure. Here, the tunneling oxide film 11 on some area of which hybrid nanoparticles 12a and 12b are not arranged can be substantially connected with the control oxide film 13.

Therefore, the tunneling oxide film 11 on the areas of which the hybrid nanoparticles are not arranged has a MOS (Metal-Oxide-Semiconductor) structure, and the tunneling oxide film 11 on the areas of which the hybrid nanoparticles 12a and 12b are arranged has a control gate 14 (metal gate)-control oxide film 13 (oxide)-nanoparticles 12a and 12b-tunneling oxide film 11 (oxide)-silicon substrate 10 (semiconductor) structure.

Therefore, when proper voltage is applied between the control gate 13 and the silicon substrate 10, charges flow in or out of the nanoparticles on the areas where the nanoparticles are arranged, to thus program/erase data. In this case, the control oxide film 13 and the tunneling oxide film 11 play a role of sustaining charges charged on the hybrid nanoparticles 12a and 12b formed as the charge trapping layer.

Hereinbelow, a method of manufacturing a nonvolatile memory device according to a preferred embodiment of the present invention will be described with reference to FIGS. 2A through 2F.

Referring to FIG. 2A, a tunneling oxide film 11 is formed in five nm thickness on a substrate 10 made of single crystal silicon. The tunneling oxide film 11 may be formed of one metal oxide of silicon oxide (SiO₂), hafnium oxide (HfO₂), aluminum oxide (Al₂O₃), zirconium oxide, zirconium silicate, and hafnium silicate.

In the case that silicon oxide (SiO₂) is used for the tunneling oxide film 11, the former may be formed as the latter through a thermal oxidation process. Meanwhile, in the case that metal oxide, for example hafnium oxide (HfO₂) is used for the tunneling oxide film. 11, the former may be evaporated as the latter through a RF-magnetron sputtering method.

Thereafter, as shown in FIG. 2B, hybrid nanoparticles 12a and 12b are attached as charge trapping layers on the tunneling oxide film 11, by a self-assembly method using mićelles.

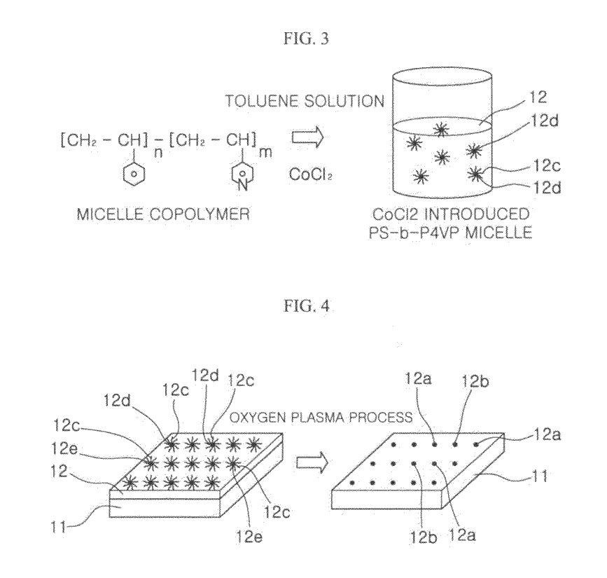

FIG. 3 is a diagram for explaining a process of preparing a copolymer micelle solution which is applied to a preferred embodiment of the present invention, and FIG. 4 is a diagram for explaining a synthesis of hybrid nanoparticles according to a preferred embodiment of the present invention.

Hereinafter, a mixture of cobalt and gold which is used as hybrid nanoparticles 12a and 12b, will be described as an example. Here, a process of preparing a copolymer micelle solution for a synthesis of cobalt nanoparticles and gold nanoparticles is same in the case of the respective hybrid nanoparticles. Accordingly, a process of preparing a copolymer micelle solution into which a cobalt nanoparticle precursor has been introduced will be described below as an example.

First, micelle copolymer formed of polymer is put in a toluene solution, to thereby form a micelle of a nano structure.

The micelles included in such a copolymer micelle solution 12 may be formed by a self-assembly method, and synthesize cobalt nanoparticles 12a of nano size.

That is, cobalt nanoparticles 12a which are used as charge trapping layers in the nonvolatile memory device according to this invention may be synthesized by introducing a precursor into a nano structure of a self-assembled micelle template 12c.

A micelle copolymer tends to phase-separate respective blocks into a domain due to a restriction of covalent bond junctions between a pair of blocks, that is, between a PS (polystyrene) corona block and a P4VP (4-Poly(vinyl pyridine)) core block, unlike a general polymer mixture showing an enormous phase separation phenomenon of several micrometers and thus form a nano structure having a size of several nanometers through several hundred nanometers by a self-assembly method.

A micelle copolymer may be formed by a polymer copolymer as expressed as the following chemical formula I using a methylene radical, a benzene radical, etc., as an example. Otherwise, a copolymer may be formed by polymer which can form micelles by a self-assembly method.

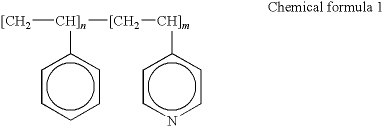

The n and m are integers in the chemical formula 1.

Form and size of a nano structure that micelle copolymer forms by a self-assembly method may be determined according to a molecular weight of the micelle copolymer, a volumetric ratio of respective blocks, a Flory-Huggins polymer solvent reciprocal action coefficient between the respective blocks, etc.

Hereinbelow, the detailed description of this invention will be made with respect to a method of controlling form and size of a nano structure by controlling a molecular weight of the micelle copolymer, that is, a method of controlling form and size of synthesized cobalt nanoparticles 12a, to thereby control a density. However, a method of controlling form and size of cobalt nanoparticles 12a, by controlling a volumetric ratio of respective blocks or a Flory-Huggins polymer solvent reciprocal action coefficient between the respective blocks does not depart off from the technical scope of this invention.

Form of a nano structure that micelle copolymer forms by a self-assembly method may be formed into with a disc style, a gyroidal style, a cylindrical style, a spherical style, a semi-spherical style, etc. Form of a nano structure that a micelle template 12c forms be controlled by controlling a molecular weight of micelle copolymer.

An optimal form of the cobalt nanoparticles 12a which are used for charge trapping layers is preferably circular on a plane because charges are easily charged and sustained when the cobalt nanoparticles 12a are circular on a plane.

In addition, in order to regularly arrange micelles of a nano structure on a ground substance such as a tunneling oxide film 11, it is preferable to arrange the micelles by using a micelle template 12c of a nano structure that is controlled in a thin film of the micelle copolymer.

That is, the micelles can be arranged on the tunneling oxide film using a strong affinity between a P4VP core block of PS-b-P4VP (polystyrene-block-poly-(4-vinyl pyridine)) micelles and the tunneling oxide film 11.

Meanwhile, a precursor 12d that can synthesize cobalt nanoparticles 12a, for example, cobalt chloride (CoCl₂) is contained in a toluene solution. Accordingly, cobalt chloride (CoCl₂) is selectively introduced into a plurality of blocks which the micelle copolymer forms in the toluene solution, that is, the P4VP core of the PS-b-P4VP micelle.

That is, the copolymer micelle solution 12 into which cobalt chloride (CoCl₂) is selectively introduced as a precursor 12d of the cobalt nanoparticles 12a in the P4VP core block of the micelle formed of a PS corona block that is soluble in solvents and a P4VP core block that is insoluble in the solvents and has a nano structure, is prepared.

In the same manner as that of preparing the copolymer micelle solution 12 into which cobalt chloride (CoCl₂) is selectively introduced as the precursor 12d of the cobalt nanoparticles 12a, a copolymer micelle solution into which gold tetrachloride acid (HAuCl₄) is selectively introduced as a precursor 12e of gold nanoparticles 12b, is prepared.

Thereafter, the copolymer micelle solution 12 into which cobalt chloride (CoCl₂) has been introduced and the copolymer micelle solution into which gold tetrachloride acid (HAuCl₄) has been introduced are mixed, and then the mixed copolymer micell solution 12 is uniformly coated on the tunneling oxide film 11 using the mixed copolymer micelle solution 12 as shown in FIG. 2B, to thus form a mono-layer film of the copolymer micelle.

In this case, the mono-layer film of the copolymer micelle coated on the tunneling oxide film 11 is formed by a self-assembly method on the tunneling oxide film 11 using a strong affinity acting between the P4VP core block of the PS-b-P4VP micelle and the tunneling oxide film 11.

Here, the copolymer micelle solution 12 may be coated on the tunneling oxide film 11 by a spin coating, a dip coating method, a spray coating method, a flow coating method or a screen printing method. It is preferable to coat the copolymer micelle solution 12 by a spin coating or dip coating method.

Then, as illustrated in FIG. 2C, a polymeric micelle template 12c is removed with respect to the copolymer micelle solution 12 coated on the tunneling oxide film 11.

A method of removing the micelle template 12c through a plasma process (for example, an oxygen plasma process) or a heat treatment process (for example, an oxygen atmosphere heat treatment process) may be largely applied, or a well-known method of removing polymeric copolymer can be applied as a method of removing the micelle template 12c.

In the case of an oxygen plasma process, oxygen is made to flow in 10 sccms (Standard Cubic Centimeter per Minute) with a MFC (Mass Flow Controller) in CVD (chemical vapor deposition) equipment, and is maintained under proper pressure, and then plasma-processed for about 10 minutes at 100 W.

Hereinbelow, a case where the micelle template 12c has been removed through the oxygen plasma process will be described' in the detailed explanation of this invention, but it can be seen that the other cases of removing the micelle template 12c are the same as that of removing the micelle template 12c through the oxygen plasma process.

Cobalt and gold nanoparticles 12a and 12b are respectively synthesized by cobalt chloride (CoCl₂) and gold tetrachloride acid (HAuCl₄) which are precursors 12d and 12e which have been selectively introduced into the P4VP core block of the micelle template 12c included in the copolymer micelle solution 12. If the micelle template 12c is removed through the oxygen plasma process, the synthesized cobalt and gold nanoparticles 12a and 12b are arranged on the tunneling oxide film 11.

Here, the cobalt nanoparticle 12a of the cobalt and gold nanoparticles 12a and 12b which are synthesized by cobalt chloride (CoCl₂) and gold tetrachloride acid (HAuCl₄) which are precursors 12d and 12e which have been selectively introduced into the P4VP core block is oxidized into cobalt oxide (CO₃O₄) that is metal oxide by the oxygen plasma process.

Here, polymer of the micelle template 12c that is included in the copolymer micelle solution 12 and arranged on the tunneling oxide film 11, is an organic matter consisting of carbon atoms (C) and hydrogen atoms (H) and thus is removed into a form of water and carbon dioxide by the oxygen plasma process.

Therefore, if the oxygen plasma treatment is made, as illustrated in FIG. 2D, only cobalt and gold nanoparticles 12a and 12b are arranged and remain on the tunneling oxide film 11.

FIG. 4 is a diagram for explaining a synthesis of hybrid nanoparticles according to an embodiment of the present invention.

Referring to FIG. 4, if the polymeric micelle template 12c is removed from the tunneling oxide film 11 through the oxygen plasma process, at the state where the copolymer micelle solution 12 including the micelle template 12c which has been obtained by selectively introducing precursors 12d and 12e (for example, cobalt chloride (CoCl₂) and gold tetrachloride acid (HAuCl₄)) into the P4VP core block to thus synthesize the cobalt and gold nanoparticles 12a and 12b, it can be seen that only cobalt and gold nanoparticles 12a and 12b are arranged on the tunneling oxide film 11.

Since the mono-layer of the copolymer micelle is formed on a ground substance (a silicon substrate) by the self-assembly method, cobalt and gold nanoparticles 12a and 12b may be arranged in a predetermined pattern on the tunneling oxide film 11.

Here, in the case that a block having a functional generator such as carboxyl radical (—COOH) or sulphonic radical (—SO₃H) forms a nano structure of the micelle, metallic salts (for example, cobalt chloride) can be introduced through an ion exchange action. Accordingly, cobalt and gold nanoparticles 12a and 12b may be synthesized by making kinds of introduced metallic salts and a post-treatment reaction differ from one another.

Thereafter, if the cobalt nanoparticle 12a is oxidized through the oxygen plasma process or the oxygen atmosphere heat treatment process after the cobalt and gold nanoparticles 12a and 12b have been arranged on the tunneling oxide film 11, as illustrated in FIG. 2E, the cobalt nanoparticle 12a is reduced through a hydrogen atmosphere heat treatment process or a hydrogen plasma process.

For example, in the case that nanoparticles 12a are synthesized with metal such as cobalt and nickel, the metallic nanoparticles 12a are oxidized at the oxygen plasma process or oxygen atmosphere heat treatment process that removes the micelle template 12c. Accordingly, the metallic nanoparticles 12a are reduced through the hydrogen plasma process or hydrogen atmosphere heat treatment process, in order to enhance electrical characteristics of the nanoparticles 12a.

Then, as illustrated in FIG. 2F, the nanoparticles 12a formed on the tunneling oxide film 11 are reduced and then a control oxide film 13 is evaporated thereon.

The oxide film of the nonvolatile memory device according to this invention, that is, the tunneling oxide film 11 and the control oxide film 13 may be formed with a hafnium oxide film, a silicon dioxide film or an aluminum oxide film by vapor deposition processes.

Then, as illustrated in FIG. 2G, a control gate 14 is formed on the control oxide film 13.

The control oxide film 13 performs the same function as that of a dielectric film in an MOS (Metal-Oxide-Semiconductor) structure, and the area of tunneling oxide film 11 which nanoparticles 12a are not arranged may be substantially connected to the control oxide film 13.

The area of the tunneling oxide film 11 which the nanoparticles are not arranged has a MOS (Metal-Oxide-Semiconductor) structure, and the area of the tunneling oxide film 11 which the nanoparticles 12a and 12b are arranged has a structure of a control gate 14 (metal gate)-a control oxide film 13-nanoparticles 12a and 12b-a tunneling oxide film 11-a semiconductor 10 sequence.

Therefore, when proper voltage is applied between the control gate 14 and the silicon substrate 10, charges flow in or out of the nanoparticles on the areas where the nanoparticles are arranged, to thus program/erase data. In this case, the control oxide film 13 and the tunneling oxide film 11 play a role of sustaining electrons charged on the hybrid nanoparticles 12a and 12b formed as the charge trapping layer.

In addition, as an area that nanoparticles 12a and 12b are arranged on the tunneling oxide film 11 is wider, characteristics of the nonvolatile memory device, that is, the flash memory device can be improved. Accordingly, it is preferable that nanoparticles 12a and 12b are densely arranged at maximum on the tunneling oxide film 11.

A density which indicates how densely nanoparticles 12a and 12b is arranged on the tunneling oxide film 11 is closely related to size and form of nanoparticles 12a and 12b. Accordingly, size and form of the nanoparticles 12a and 12b by controlling a molecular weight of the micelle copolymer may be controlled, to thereby control an arrangement density of the nanoparticles 12a and 12b at maximum.

That is, control of the sizes of the nanoparticles 12a and 12b can be controlled by controlling a molecular weight of the P4VP core block, or an amount of precursors 12d and 12e that are introduced in the P4VP core block, and an interval between the nanoparticles 12a and 12b can be controlled by controlling a molecular weight of the PS corona block. Accordingly, density of the nanoparticles 12a and 12b can be controlled by controlling the molecular weights of the PS corona block and the P4VP core block of the micelle copolymer.

Therefore, density of the nanoparticles 12a and 12b can be established into 10¹² cm⁻² by controlling the molecular weight of the micelle copolymer.

It is possible to change size and/or density of the micelle by controlling a chemical affinity between respective blocks with respect to solvents, a chemical miscibility between the blocks, a mole weight of each block, and a ratio between the blocks. This means that size and/or density of nanoparticles can be changed.

Hereinbelow, a sample of the nonvolatile memory device of this invention is fabricated to thus review characteristics thereof.

### Embodiment

### A. Preparation of Substrate

A specimen has been fabricated on a p-type silicon substrate (the (100) direction, 1 through 10 ohm-cm substrate fabricated in the Siltron™). The specimen has been washed by using a sulfuric acid to hydrogen peroxide (7:3) mixture solution at a pretreatment process, and nature oxide films have been removed by using a fluoric acid and then washed by using ultrapure water.

### B. Formation of Tunneling Oxide Film

HfO₂ of 5 nm thicknesses has been evaporated as a tunneling oxide film by using RF-magnetron sputtering equipment. HfO₂ has progressed with a Hf target by a reactive ion sputtering method under an argon and oxygen atmosphere. A base pressure has been kept as 10⁻⁶ Torr or less and a process pressure has been kept as 20 mTorr.

### C. Formation of Cobalt Nanoparticles and Gold Nanoparticles for Use in Charge Trapping Layers

Numerous cobalt nanoparticles and gold nanoparticles have been discontinuously dispersed on the HfO₂-coated silicon substrate as charge trapping layers by a self-assembly method that uses micelles.

(1) Preparation of Copolymer Micelle (Charge Trapping Layer) Solution

Polystyrene-block-poly(4-vinylpyridine)(PS-b-P4VP) has been used as the micelle copolymer for synthesis of cobalt nanoparticles and gold nanoparticles. Numerical average molecular weights of PS and P4VP were 31,900 and 13,200 gmol⁻¹, and a polydispersity index was 1.06.

In order to make the copolymer micelle solution, a PS-b-P4VP micelle was mixed into a toluene solution (with toluene of generally 0.5 wt %) which acts as a strong selective solvent with respect to the PS block, and stirred for 2 hours at room temperature and for 3 hours at 75° C., to then be cooled to room temperature.

As precursors of Co and Au nanoparticles to be synthesized, CoCl₂ and HAuCl₄ have been mixed in the copolymer micelle 0.5 wt % toluene solution, and then stirred for at least 3 days. Here, a molar ratio of the respective precursor with respect to vinyl pyridine was kept as 0.5.

Then, in order to prepare the micelle mixture solution, the respective solutions containing CoCl₂ and HAuCl₄ were mixed by the same amount at room temperature.

(2) Arrangement of Cobalt Nanoparticles and Gold Nanoparticles

The prepared micelle mixture solution has been spin coated for 60 seconds at 2000 rpm on the Si substrate on which HfO₂ was formed and thus a mono-layer of the copolymer micelle has been formed by a self-assembly method. Then, the mono-layer of the copolymer micelle in which the precursors were included has been processed for 10 minutes by an oxygen plasma process (whose plasma power is 100 W and process pressure is 20 mTorr), to thereby remove the copolymer and to form the cobalt nanoparticles and gold nanoparticles.

(3) Measurement of the Synthesized Cobalt and Gold Nanoparticles

In order to confirm the synthesized cobalt and gold nanoparticles, a TEM (Transmission Electron Microscopy) image of PS-b-P4VP micelle into which CoCl₂ and HAuCl₄ were introduced has been photographed instead of photographing an image of nanoparticles after having performed a plasma treatment operation and shown in FIG. 1. This is because the PS-b-P4VP micelle which CoCl₂ and HAuCl₄ were introduced could be definitely distinguished as the images.

Reviewing the TEM image appearing on the lower portion of FIG. 1, the PS-b-P4VP micelle which HAuCl₄ was introduced could be identified as a micelle having several small particles due to a fast reduction of HAuCl₄. Meanwhile, the PS-b-P4VP micelle into which CoCl₂ was introduced has appeared as a gray spherical domain from which no particles were visible.

In FIG. 1, the TEM image located on the upper portion of FIG. 1 shows the PS-b-P4VP micelle which CoCl₂ was introduced for comparison with this invention, the TEM image located in the middle of FIG. 1 shows the PS-b-P4VP micelle which HAuCl₄ was introduced for comparison with this invention, and the TEM image appearing on the lower portion of FIG. 1 shows the PS-b-P4VP micelle into which CoCl₂ and HAuCl₄ were respectively introduced using the micelle mixture solution according to the present invention.

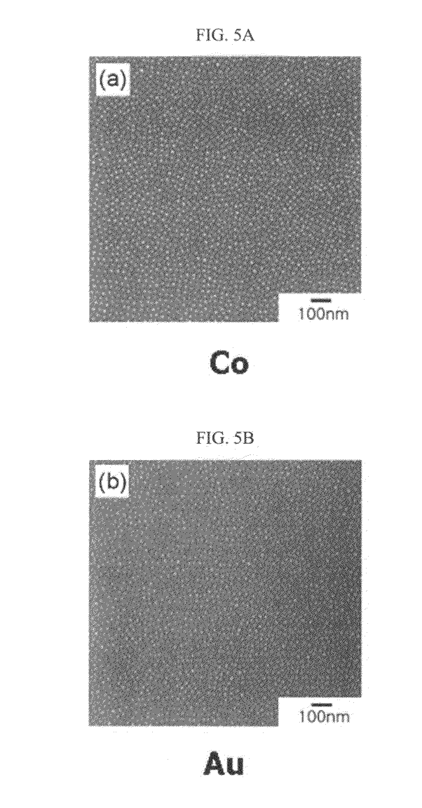

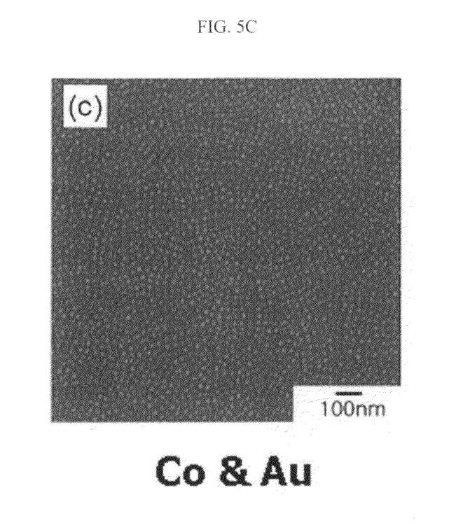

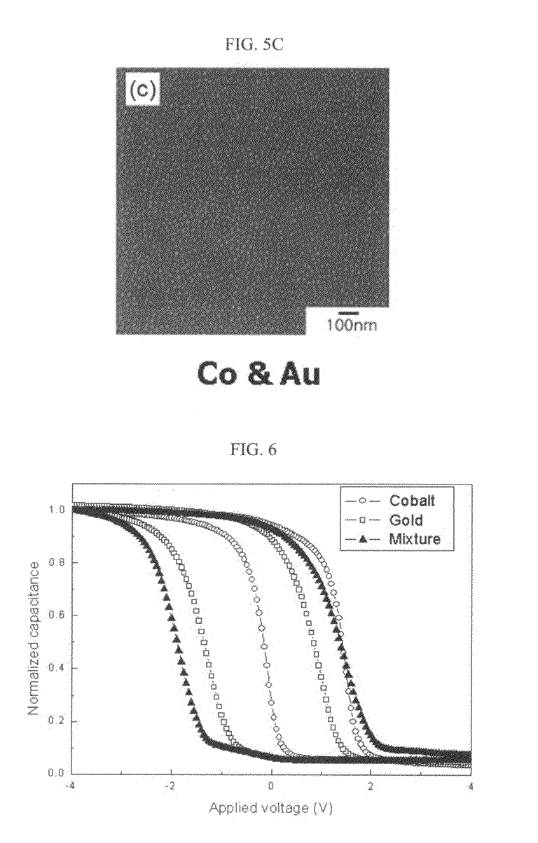

In addition, images of the Co, Au and Co & Au nanoparticles after having performed the plasma treatment are shown in FIGS. 5A to 5C. Referring to FIGS. 5A to 5C, samples of the synthesized cobalt nanoparticles, gold nanoparticles and cobalt/gold nanoparticles have a distribution of 11.4×2.3 nm in size and a density of 1.3×10¹¹ cm⁻².

### D. Formation of Control Oxide Film/Gate Electrode

After that, HfO₂ of 15 nm thick has been evaporated as the control oxide film by the same reactive ion sputtering method as that of the tunneling oxide film. Then, Pt of 100 nm thick has been evaporated as a gate electrode (control gate) by a DC magnetron sputtering method at ordinary temperature. Here, a base pressure was kept as 10⁻⁶ or below and a process pressure was kept as 3 mTorr. The gate electrode was patterned in an area of 4.70×10⁻⁵ cm² by using a lift-off process. A copper plate was attached on the substrate for ground connection by using silver paint.

In the embodiment of the present invention, the cobalt/gold nanoparticle mixture structure was formed as the charge trapping structure, and the respective structures were formed to thus have performed an estimation of electrical characteristics. In this case, the cobalt nanoparticle structure and the gold nanoparticle structure were formed to thus have been compared with the structure of the present invention.

FIG. 6 is a graphical view that represents a change in memory characteristics when cobalt nanoparticles, gold nanoparticles, and nanoparticles of a mixture of Co and Au were formed.

Referring to FIG. 6, it can be seen that a programming operation has been easily performed when the cobalt nanoparticles were used as charge trapping layers, a programming/erasing operation has been easily performed when the gold nanoparticles were used as charge trapping layers, and an erasing operation has been easily performed when the cobalt and gold mixture nanoparticles were used as charge trapping layers, under an identical programming/erasing operational condition.

These memory characteristics can be interpreted by an electron affinity of the used nanoparticles and a transfer and redistribution of charges in the nanoparticles.

Since surfaces can be easily oxidized in the case of the cobalt nanoparticles, a core shell structure of a cobalt/cobalt oxide structure can be formed. As a result, a programming operation goes well, but an erasing operation can be blocked.

Since an electron affinity is very big in the case of the gold nanoparticles, the gold nanoparticles may have partially stored electrons at an initial state. As a result, electrons stored in an erasing operation can be removed well, in the case of the gold nanoparticles, but it is difficult to program electrons in the programming operation due to the Coulomb barrier effect of the already-stored electrons as in the case of the cobalt nanoparticles.

That is, since electrons are hardly included at the initial state in the case of the cobalt nanoparticles, a program operation can be made well. However, since electrons are already included at the initial state in the case of the gold nanoparticles, electrons may be trapped to a degree and electrons are difficult to be trapped by the Coulomb repulsion force of the already-stored electrons unlike the case of the cobalt nanoparticles. Thus, in the case of the gold nanoparticles, it is difficult to perform the program operation due to the electrical characteristics of the gold nanoparticles.

However, in the case of the mixture nanoparticles of this invention, the stored charges can be easily transferred due to respectively different electronegativities between the nanoparticles. As a result, electrons stored in the cobalt nanoparticles as well as electrons stored in the gold nanoparticles can be easily removed through the gold nanoparticles, during an erasure operation. As a result, it can be confirmed that more electrons can be removed in a structure of gold and cobalt mixture nanoparticles than a structure of nanoparticles of a gold single element during an erasure operation.

In addition, when a hybrid mixture layer of respectively different kinds of gold and cobalt is used, both the program and erasure operations are made well by help of cobalt nanoparticles during performing a program operation and gold nanoparticles during performing an erasure operation. These features are shown well in FIG. 6.

Therefore, if the mixture layer of the respectively different kinds of gold and cobalt nanoparticles is used as charge trapping layers, a controllable memory characteristics which cannot be obtained in a memory device using nanoparticles of a single element may be obtained.

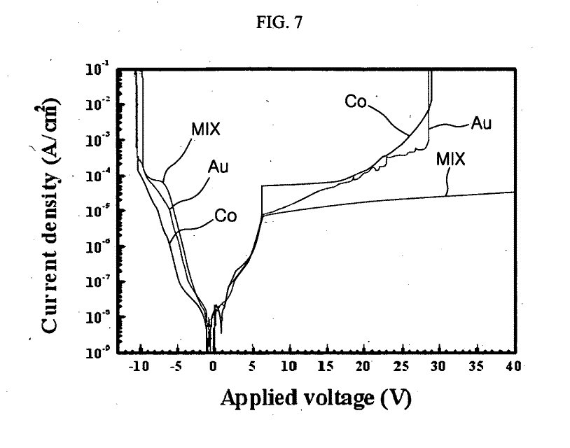

FIG. 7 is a graphical view that represents gate tunneling electric current values according to voltage values which is applied to respectively formed memory devices.

The gate tunneling electric current values of FIG. 7 relate to a transfer of charges to nanoparticles from a silicon substrate in a positive voltage region, and relate to a transfer of charges to the silicon substrate from the nanoparticles in a negative voltage region.

In the case that cobalt nanoparticles are used as charge trapping layers, the highest electric current value has appeared in the positive voltage region, but in the case that gold and cobalt mixture nanoparticles are used as charge trapping layers, the highest electric current value has appeared in the negative voltage region. It can be confirmed that these characteristics are very identical with the memory characteristics having appeared in the capacitance measurement of FIG. 6.

If a gate bias of 30V or more is applied to a device having charge trapping layers of nanoparticles of a single element such as cobalt nanoparticles and gold nanoparticles, a breakdown phenomenon may happen. However, although a gate bias of 30V or more is applied to a device according to the present invention, it can be seen that no breakdown phenomena happen.

This means that an increase of the gate voltage may accomplish a programming operation which is better than that of an initial state. This also means that a program operation of a memory device can continue because the higher voltage applied can overcome the coulomb repulsion force of the trapped charges.

Meanwhile, when analyzing a tunneling mechanism, a Fowler-Nordheim (F-N) tunneling is a main tunneling mechanism in the case of nanoparticles containing only one element. However, in the present invention which uses the hybrid mixture nanoparticles as charge trapping layers, the F-N tunneling and Poole-Frenkel (P-F) conduction appear as a dominant conduction mechanism in a program bias range. The P-F conduction relates to a transfer of charges in a bulk material filled with charged defectives.

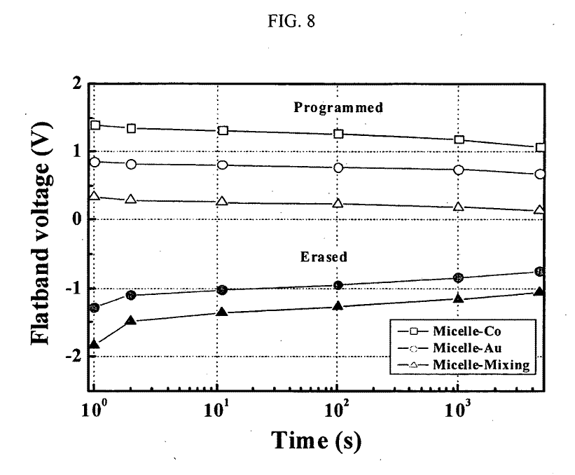

FIG. 8 is a graphical view which represents pictures in which very different critical voltage values (V_{FB}) of respectively formed devices are extracted to then test an information storage capacity, respectively. In FIG. 8, 6 data levels of 3 devices have actually existed, but the erasure state that uses the cobalt nanoparticles as the charge trapping layers has been excluded since the erasure state using the cobalt nanoparticles is nearly same as that of the device using the mixture nanoparticles of Co and Au. In the result of testing the information storage capacity by time, it can be seen that 5 data levels are well kept.

FIG. 10 is a graphical view that represents a flat band voltage shift which is obtained by nanoparticles used in a memory device according to the present invention. Data levels of 0, 1, 2, 3 and 4 represent memory states of an erase cell having a mixture of Co and Au and an erase cell having Au, and memory states of a programmed cell having a mixture of Co and Au, and programmed cells having Au and Co, respectively.

As shown in FIG. 10, programmable memory characteristics can be controlled by using different flat band voltage values according to the kind of the charge trapping layers in the present invention. By using the programmable memory characteristics, a multilevel programmable/accessible memory device can be implemented in the present invention. It is important to sustain a multiplex data level according to passage of time for storing multiplex data.

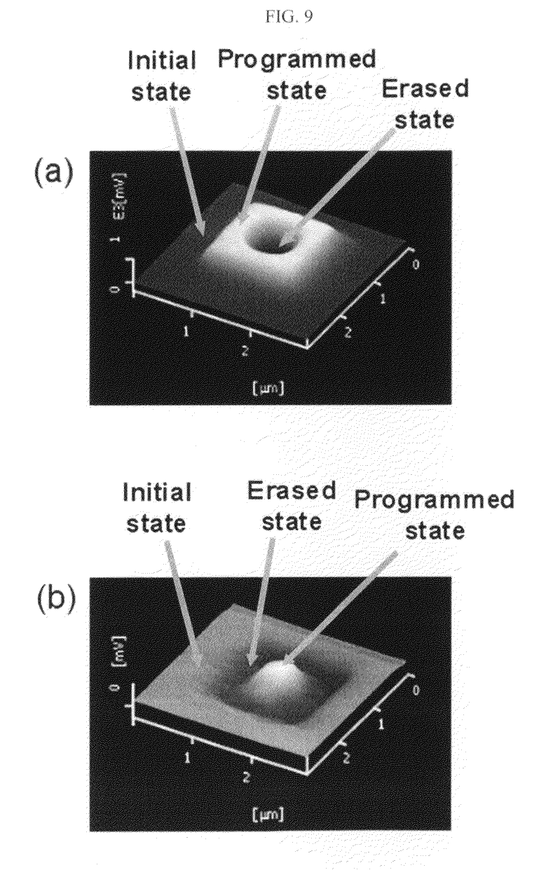

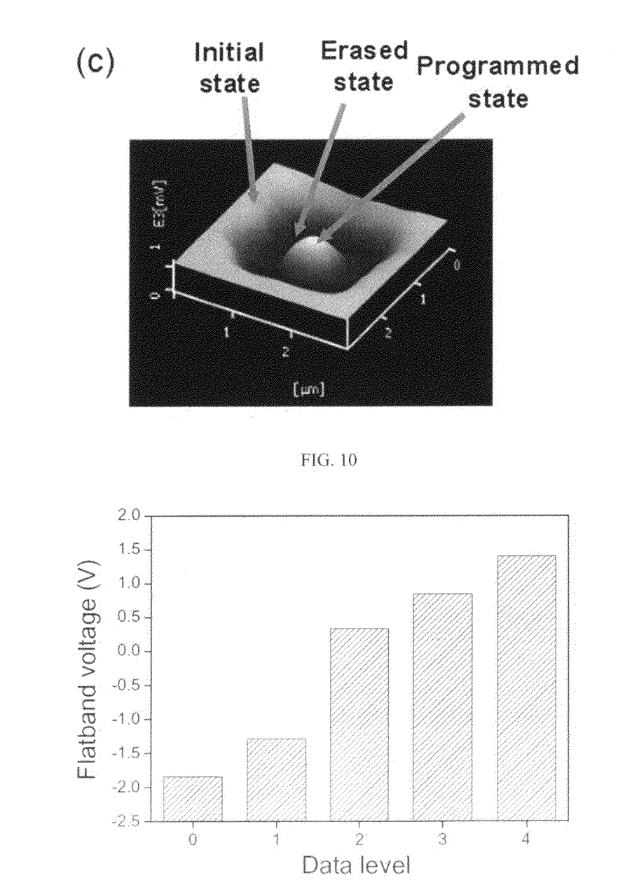

FIGS. 9A through 9C show operational characteristics in nano kale in respectively formed memory devices, as Kelvin Force Microscopy (KFM) images.

The KFM equipment measures difference of surface potentials, and shows difference of surface potentials as a difference in contrast. Here, bright portions represent program states and dark portions represent erasure states.

Prior to performing the KFM measurement, a program operation has proceeded in the case of a device using cobalt nanoparticles in size of 1.5×1.5 μm², and an erasure operation has proceeded in the case of a device using gold and cobalt mixture nanoparticles, by using a contact mode of the KFM equipment.

Then, an erasure operation has proceeded in the case of a device using cobalt nanoparticles in size of 500×500 μm², and a program operation has proceeded in the case of a device using gold and cobalt mixture nanoparticles. Thereafter, a surface electric potential has been measured in size of 3×3 μm², by using the KFM mode.

As a result, it can be seen that a program operation has proceeded well in the case of using cobalt nanoparticles as the charge trapping layers, a program/erasure operation has proceeded well in the case of using gold nanoparticles as the charge trapping layers, and an erasure operation has proceeded well in the case of using gold and cobalt mixture nanoparticles as the charge trapping layers, even in nano scale.

In the above-described embodiment, the case of using the hybrid nanoparticles where cobalt nanoparticles and gold nanoparticles are mixed as charge trapping layers, has been described as an example, but it is apparent that nonvolatile memory devices having various memory characteristics can be obtained by mixing various kinds of nanoparticles of two or more elements at a desired ratio.

As described above, according to this invention, density and size of charge trapping layers in a nonvolatile memory device can be easily controlled and the charge trapping layers can be formed into nanoparticles of nano size.

According to this invention, nanoparticles can be formed by using micelles which are self-assembled, to thus prevent problems such as change in characteristics of membranes due to a heat treatment process of high temperature which forms nanoparticles, in advance.

In addition, according to this invention, a tunneling oxide film or control oxide film is formed of a hafnium oxide film having a high dielectric constant, to thereby apply a high electric field more than an existing nonvolatile memory device at identical voltage, and to thus improve memory device characteristics.

As described above, hybrid nanoparticles are used as charge trapping layers in a nonvolatile memory device in this invention, to thereby enhance memory characteristics. The hybrid nanoparticles which are used as charge trapping layers can be applied to a flash memory device.

The present invention has been described in detail with respect to the embodiment but is not limited to the above-described embodiments. It is apparent to one who has an ordinary skill in the art that there may be many modifications and variations within the same technical spirit of the invention. It is natural that the modifications and variations belong to the following appended claims.

What is claimed is:

1. A charge trapping layer for use in a nonvolatile memory device, the charge trapping layer comprising a number of nanoparticles which are discontinuously formed between a tunneling barrier layer and a control barrier layer, and comprise at least two respectively different kinds of elements.

2. The charge trapping layer for use in a nonvolatile memory device, according to claim 1, wherein the respectively different kinds of the nanoparticle elements comprise: first nanoparticle element used for programming operations; and second nanoparticle element used for erasing operations.

3. The charge trapping layer for use in a nonvolatile memory device, according to claim 2, wherein the first nanoparticle element comprises at least one of cobalt (Co) and copper (Cu), and the second nanoparticle element comprises at least one of gold (Au) and platinum (Pt).

4. The charge trapping layer for use in a nonvolatile memory device, according to claim 1, wherein the respectively different kinds of the nanoparticle elements are synthesized by a soluble corona block and an insoluble core block in solvents to produce micelles, and are formed by using inorganic precursors of at least two respectively different kinds in order to synthesize at least two respectively different kinds of nanoparticle solutions by a self-assembly method.

5. A nonvolatile memory device comprising:
a semiconductor substrate;
a tunneling barrier layer formed on the semiconductor substrate;
a charge trapping layer comprising a number of nanoparticles discontinuously formed on the tunneling barrier layer and comprise at least two respectively different kinds of elements;
a control barrier layer formed on the tunneling barrier layer and the nanoparticles of the charge trapping layer; and
a control gate formed on the control barrier layer.

6. The nonvolatile memory device according to claim 5, wherein the respectively different kinds of the nanoparticle elements comprise: first nanoparticle element used for programming operations; and second nanoparticle element used for erasing operations.

7. The nonvolatile memory device, according to claim 6, wherein the first nanoparticle element comprises at least one of cobalt (Co) and copper (Cu), and the second nanoparticle element comprises at least one of gold (Au) and platinum (Pt).

8. The nonvolatile memory device according to claim 5, wherein the respectively different kinds of the nanoparticles comprise: at least two selected from the group consisting of Co, Fe, Ni, Cr, Au, Ag, Cu, Al, Pt, Sn, W, Ru, Pd, Cd, Si, Ge, and SiGe.

9. The nonvolatile memory device according to claim 5, wherein the respectively different kinds of the nanoparticles are synthesized by a soluble corona block and an insoluble core block in solvents to produce a copolymer micelle, and are formed on the tunneling barrier layer in a predetermined pattern by a self-assembly method using the copolymer micelle.

10. The nonvolatile memory device according to claim 9, wherein the charge trapping layer is formed by mixing respectively different kinds of charge trapping layer formation solutions which are obtained by using the copolymer micelle and at least two respectively different kinds of inorganic precursors.

11. The nonvolatile memory device according to claim 5, wherein the charge trapping layer comprises the at least two respectively different kinds of nanoparticles, to thus form a multilevel programmable/accessible memory which is proportional with the kinds of the used nanoparticles.

12. The nonvolatile memory device according to claim 5, wherein the nonvolatile memory device causes no breakdown phenomenon in a positive voltage region.

13. A method of forming a charge trapping layer on a semiconductor substrate, the method comprising the steps of:
forming a tunneling barrier layer on the semiconductor substrate;
preparing at least two different kinds of charge trapping layer formation solutions in which a block copolymer micelle that is composed of a soluble corona block and an insoluble core block in solvents and that forms a nanostructure by a self-assembly method, and at least two different kinds of inorganic precursors are dissolved in the solvents, respectively, and thus the inorganic precursors are selectively introduced in the core block playing a role of a micelle template;
mixing the at least two different kinds of charge trapping layer formation solutions at a desired ratio, to thus obtain a charge trapping layer formation solution mixture;
coating the mixture on the tunneling barrier layer and arranging a number of micelle templates into which the inorganic precursors are respectively introduced by the self-assembly method; and
removing the micelle templates to thus arrange different kinds of nanoparticles which are synthesized from the inorganic precursors on the tunneling barrier layer in a predetermined pattern of nano size and to thereby form a charge trapping layer.

14. The charge trapping layer forming method of claim 13, wherein the respectively different kinds of the nanoparticle elements comprise: first nanoparticle element used for programming operations; and second nanoparticle element used for erasing operations.

15. The charge trapping layer forming method of claim 14, wherein the first nanoparticles comprise at least one of cobalt (Co) and copper (Cu), and the second nanoparticles comprise at least one of gold (Au) and platinum (Pt).

16. The charge trapping layer forming method of claim 13, wherein the block copolymer micelle is formed of PS-b-P4VP (polystyrene-block-poly(4-vinyl pyridine).

17. A method of fabricating a nonvolatile memory device, the method comprising the steps of
forming a tunneling barrier layer on a semiconductor substrate;
preparing at least two different kinds of charge trapping layer formation solutions in which a block copolymer micelle that is composed of a soluble corona block and an insoluble core block in solvents and that forms a nanostructure by a self-assembly method, and at least two different kinds of inorganic precursors are dissolved in the solvents, respectively, and thus the inorganic precursors are selectively introduced in the core block playing a role of a micelle template;
mixing the at least two different kinds of charge trapping layer formation solutions at a desired ratio, to thus obtain a charge trapping layer formation solution mixture;
coating the mixture on the tunneling barrier layer;
removing the micelle templates to thus arrange different kinds of nanoparticles which are synthesized from the inorganic precursors on the tunneling barrier layer in a predetermined pattern of nano size and to thereby form a charge trapping layer;
forming a control oxide film on the tunneling oxide film and the nanoparticles; and
forming a control gate on the control oxide film.

18. The nonvolatile memory device fabrication method of claim 17, wherein the respectively different kinds of the nanoparticle elements comprise: first nanoparticle element used for programming operations; and
second nanoparticle element used for erasing operations.

19. The nonvolatile memory device fabrication method of claim 18, wherein the first nanoparticles comprises at least one of cobalt (Co) and copper (Cu), and the second nanoparticles comprises at least one of gold (Au) and platinum (Pt).

20. The nonvolatile memory device fabrication method of claim 17, wherein density of the nanoparticles is controlled by controlling a molecular weight of the corona and the core blocks of the block copolymer.

21. The nonvolatile memory device fabrication method of claim 20, wherein size of the nanoparticles is controlled according to a molecular weight of the core block or an amount of the precursor introduced into the core block, and interval of the nanoparticles is controlled according to the molecular weight of the core block.

22. The nonvolatile memory device fabrication method of claim 17, wherein the step of Coating the mixture on the tunneling barrier layer comprises a step of forming a mono-layer of the block copolymer micelle on the tunneling barrier layer by a self-assembly method.

23. The nonvolatile memory device fabrication method of claim 22, wherein the block copolymer micelle is formed of PS-b-P4VP (polystyrene-block-poly(4-vinyl pyridine).

24. The nonvolatile memory device fabrication method of claim 17, wherein the micelle template is removed through a plasma process or a heat treatment process.

25. The nonvolatile memory device fabrication method of claim 17, wherein the step of coating the mixture on the tunneling barrier layer comprises a step of arranging a number of micelle templates into which inorganic precursors are introduced on the tunneling barrier layer in nano size by a self-assembly.

26. The nonvolatile memory device fabrication method of claim 17, wherein the step of coating the mixture on the tunneling barrier layer comprises a step of using any one selected from the group consisting of a spin coating method, a dip coating method, a spray coating method, a flow coating method and a screen print method.

27. The nonvolatile memory device fabrication method of claim 17, wherein the respectively different kinds of nanoparticles that form the charge trapping layer are cobalt nanoparticles and gold nanoparticles.
